(19) United States
(12) Patent Application Publication
(10) Pub. No.: US 2026/0206581 A1
(43) Pub. Date: Jul. 16, 2026

(54) HEAT SINK FOR A SEMICONDUCTOR PACKAGE, PANEL-LEVEL HEAT SINK ARRAY AND RELATED MANUFACTURING METHOD

(71) Applicant: Chengdu Monolithic Power Systems Co., Ltd., Chengdu (CN)

(72) Inventors: Yingjiang Pu, Chengdu (CN); Hunt Hang Jiang, Saratoga, CA (US); Jinghai Zhou, Bellevue, WA (US)

(21) Appl. No.: 19/445,057

(22) Filed: Jan. 9, 2026

(30) Foreign Application Priority Data
Jan. 10, 2025 (CN) 202510044971.4

(51) Int. Cl. H10W 40/22; H10W 40/00; H10W 40/20; H10W 74/10

(52) U.S. Cl. CPC H10W 40/22; H10W 40/033; H10W 40/233; H10W 40/242; H10W 74/114

(57) ABSTRACT

The present application discloses a semiconductor package with integrated heat sink. The semiconductor package includes at least one semiconductor die that is considered the primary heat source. A heat sink partially embedded in the encapsulation material is coupled to the backside of the semiconductor die. The heat sink includes at least one connection rib that is encapsulated by an encapsulating material. Even if the semiconductor package is turned over, the encapsulation material can still provide sufficient mechanical support for the heat sink through contact with the at least one connection rib, ensuring that the heat sink is firmly fixed and is not easy to fall off.

### CROSS-REFERENCE TO RELATED APPLICATIONS

The present application claims the benefit and priority of CN Patent Application Serial No. 202510044971.4 filed on January 10, 2025, and hereby incorporated fully by reference into the present application.

### TECHNICAL FIELD

This application relates to semiconductor packages, and more specifically, to a heat sink for a semiconductor package structure and a manufacturing method thereof.

### BACKGROUND OF THE INVENTION

Power semiconductor devices are widely used in many fields due to their key functions in power conversion and circuit control. For example, in the field of new energy vehicles, power semiconductor devices play a critical role in battery management and motor drive systems; in the consumer electronics industry, they are widely used in smartphones and smart home appliances; and in the communications industry, power semiconductor chips are extensively used in communication base stations and data centers. After a power semiconductor device is fabricated as a power semiconductor die, it is typically mounted within a semiconductor package unit, either alone or with other devices/dies, so that the power semiconductor die could be coupled to the support structure (e.g. a printed circuit board) in a fully protected state.

In a semiconductor package including the power semiconductor die, a heat dissipation design of the semiconductor package unit needs to be particularly optimized to avoid overheating. The primary function of the heat sink is to remove heat from the semiconductor package unit. For this reason, coupling a heat sink to the power semiconductor die is a common design approach. Typically, one surface of the heat sink is exposed from the encapsulation material of the semiconductor package to conduct heat to the environment. However, after prolonged use, there is a risk of the heat sink delaminating and detaching from the exposed opening.

### BRIEF DESCRIPTION OF DRAWINGS

For a better understanding of the present disclosure, embodiments of the invention will be described in accordance with the following drawings, which are used for illustrative purposes only. The drawings illustrate only some of the features in an embodiment. It should be understood that the drawings are not necessarily to scale. Like elements are provided with like reference numerals in different appended drawings.

FIG. 1A is a schematic cross-sectional view of a semiconductor package unit 202 with an integrated heat sink 301 according to an embodiment of the present application.

FIG. 1B is a schematic diagram of the semiconductor package unit 202 of FIG. 1A after being inverted.

FIG. 1C is a schematic cross-sectional view of the semiconductor package unit 202 with an integrated heat sink 301 according to another embodiment of the present application.

FIG. 2A is a schematic top plan view of a panel-level chip unit array 200 according to an embodiment of this application.

FIG. 2B is a schematic top plan view of a panel-level heat sink array 300 according to an embodiment of the present application.

FIG. 2C is an enlarged schematic view of a portion 302 of the panel-level heat sink array 300 according to an embodiment of this application.

FIG. 2D is an enlarged schematic view of the portion 302 of another exemplary panel-level the heat sink array 300 according to another embodiment of this application.

FIG. 2E is a schematic top plan view of a panel-level heat sink array 400 according to an embodiment of the present application.

FIG. 2F is a schematic plan top view of a panel-level heat sink array 500 according to an embodiment of this application.

FIG. 3A to FIG. 3E illustrate schematic cross-sectional views or top views of some stages in a method of fabricating the semiconductor package unit 202 with integrated heat sink according to an embodiment of the present application.

FIG. 4 shows a state when the portion 302 of the panel-level heat sink unit array 300 as illustrated in FIG. 2C is in the step as shown in FIG. 3D.

FIG. 5A to FIG. 5G illustrate cross-sectional views or top views of some stages in a method of fabricating the semiconductor package unit 202 with integrated heat sink in accordance with another embodiment of the present disclosure.

FIG. 6A to FIG. 6F are schematic cross-sectional views of some stages in a method for manufacturing the semiconductor package unit with integrated heat sink according to another embodiment of this application.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phrases "one embodiment", "an embodiment", "an example" and "examples" are not necessarily directed to the same embodiment or example. Furthermore, the features, structures, or characteristics may be combined in one or more embodiments or examples.

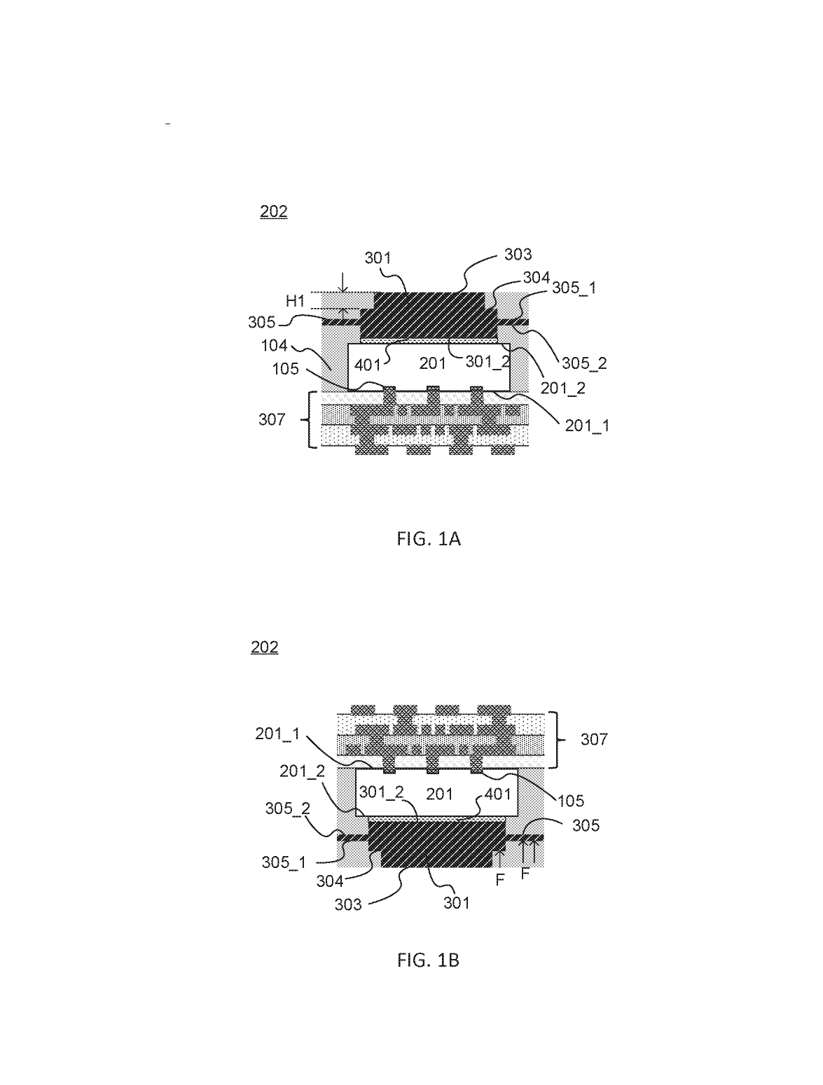

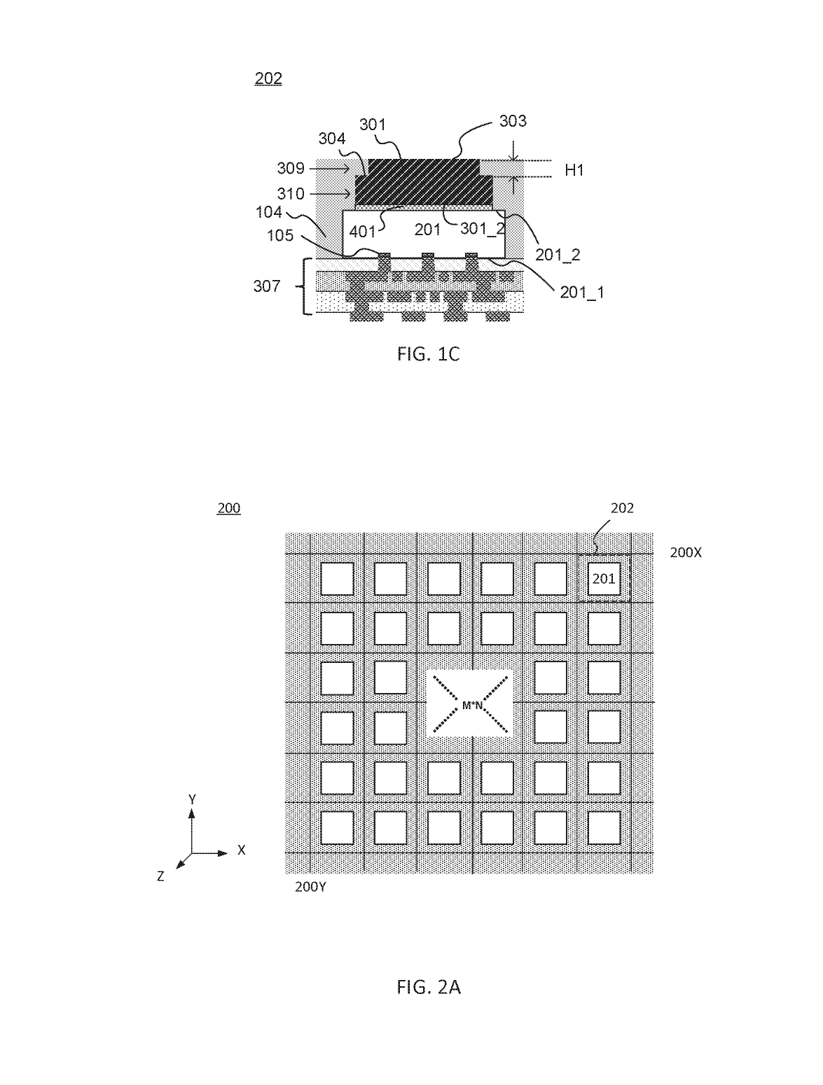

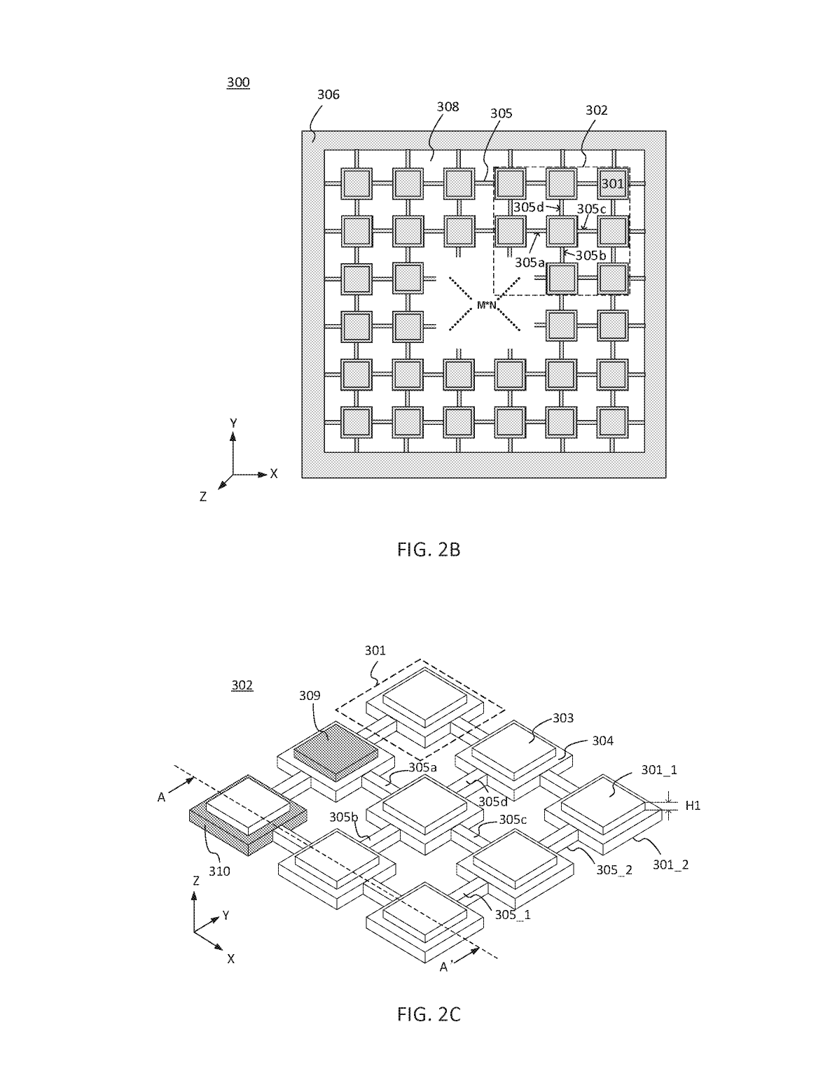

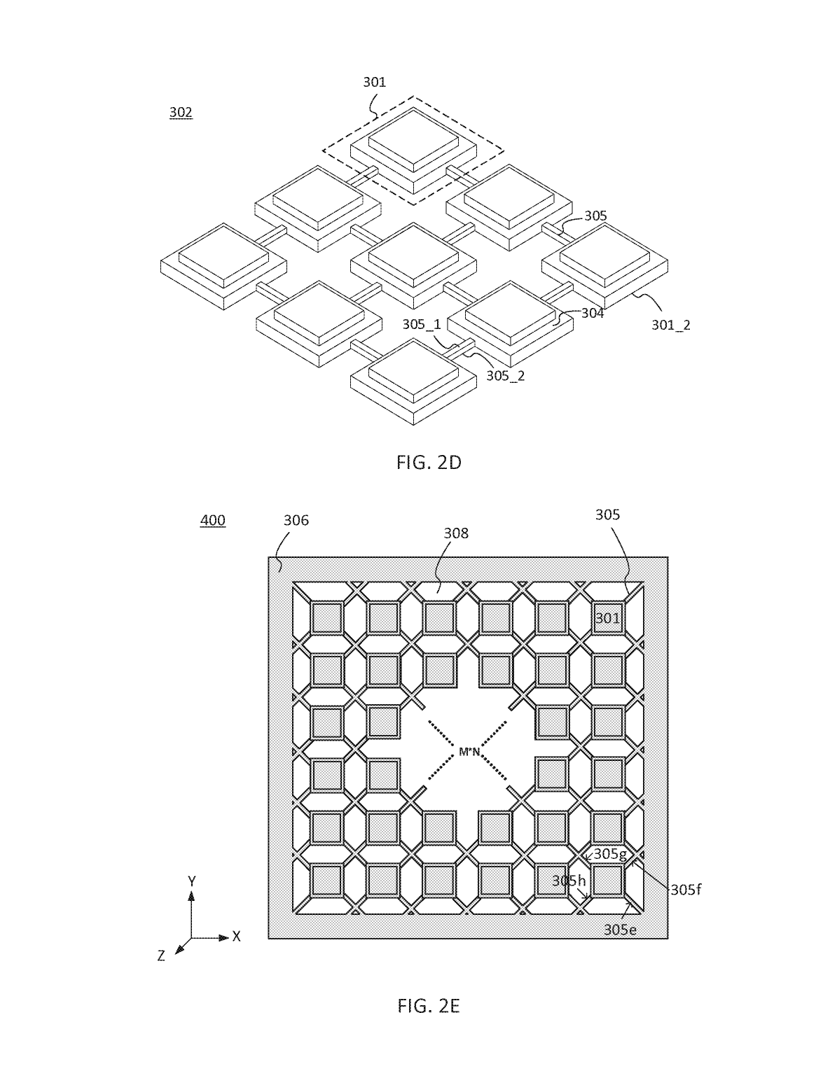

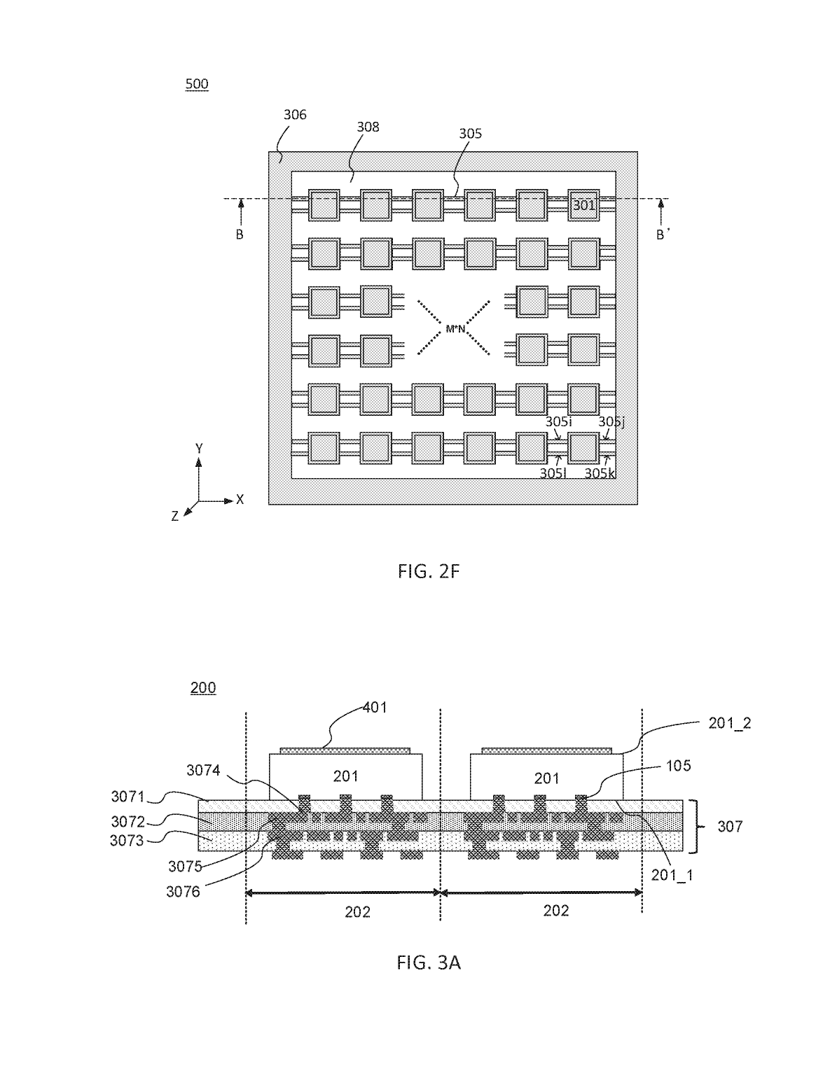

FIG. 1A illustrates a cross-sectional view of a semiconductor package unit 202 according to an embodiment of the present disclosure. In this embodiment, the chip unit 201 of the semiconductor package unit 202 includes only one semiconductor die (labeled as 201), which is the main heat source, i.e., the object that needs to be designed with the heat dissipation solution according to the present application. Those skilled in the art must understand that in other embodiments, the chip unit 201 may include multiple semiconductor dies, one or several of which are the primary heat source. The semiconductor die 201 of FIG. 1A may include a substrate on which integrated circuits are fabricated, which may be coupled to external circuits through a plurality of metal pads 105. In the example of FIG. 1A, the semiconductor die 201 is arranged on a laminated substrate 307 and forms conductive paths through electrical coupling of metal pads 105 with redistribution structures within the laminated substrate 307. The side of the semiconductor die 201 on which metal pads 105 are fabricated may be referred to as a front side 201_1, and the side opposite to the front side 201_1 may be referred to as a back side 201_2. An adhesive material layer 401 for bonding a heat sink unit 301 is correspondingly disposed on the back side 201_2 of the semiconductor die 201, and the adhesive material layer 401 may be a material with good thermal conductivity and good bonding performance. The heat sink unit 301 is adhered to the adhesive material layer 401. All or at least a portion of a surface of one side of the heat sink unit 301 is exposed from the encapsulation material 104 to conduct heat out of the semiconductor package unit 202. A connection rib 305 connected to the heat sink unit 301 can also be seen from the cross-sectional view of FIG. 1A. The connection rib 305 extends beyond the boundary of the heat sink unit 301 and is wrapped by the encapsulation material 104. A surface of the connection rib 305 close to a first step plane 303 may be referred to as a first plane 305_1, a surface of the connection rib 305 away from the first step plane 303 may be referred to as a second plane 305_2, and the first plane 305_1 is completely covered by the encapsulation material 104. In an embodiment, referring to FIG. 1A, the heat sink unit 301 has a stepped structure, that is, the heat sink unit 301 includes a first step plane 303 and a second step plane 304, and there is a height difference H1 between the first step plane 303 and the second step plane 304 in a direction perpendicular to the front side 201_1. In the embodiment of FIG. 1A, the first plane 305_1 of the connection rib 305 is not coplanar with the second step plane 304, and the second plane 305_2 of the connecting rib 305 is not coplanar with a bottom surface 301_2 of the heat sink unit 301. However, in the examples shown in FIG. 2C and FIG. 2D, such configuration is not required. FIG. 1B shows a schematic diagram after the semiconductor package unit 202 of FIG. 1A is inverted, in this state, the first step plane 303 faces downward, and when it is under this gravity condition for a long time or under other external forces, the encapsulation material 104 can still provide sufficient mechanical support to the heat sink unit 301 through contact with the entire surface of the second step plane 304 and contact with the first plane 305_1 of the connection rib 305 (the mechanical support effect is represented by arrow F in FIG. 1B), ensuring that the entire heat sink unit 301 is firmly fixed in the semiconductor packaging unit 202 and is not easy to fall off. FIG. 1A just illustrates a cross-sectional view of a semiconductor package unit 202 according to an exemplary embodiment of the inventive concept disclosed in the present application, and after reading the entire specification and drawings, those skilled in the art should understand that semiconductor package units according to other embodiments of the inventive concept disclosed in the present application are not necessarily completely as shown in FIG. 1A, for example, the number and positions of the connection ribs 305 can be flexibly adjusted.

Referring to the embodiment of FIG. 1C, one difference from FIG. 1A is that the heat sink unit 301 in the packaging unit 202 is not provided with the connection rib 305. In the embodiment of FIG. 1C, the heat sink unit 301 also has a stepped structure, that is, the heat sink unit 301 includes the first step plane 303 and the second step plane 304, and there is also the height difference H1 between the first step plane 303 and the second step plane 304 in a direction perpendicular to the front side 201_1. To introduce and describe the structure of the heat sink unit 301 from another perspective, the heat sink unit 301 includes a first step portion 309 and a second step portion 310, the first step portion 309 is vertically stacked on the second step portion 310, the first step portion 309 has a first step plane 303, the second step portion 310 has a second step plane 304, and there is a height difference H1 between the first step plane 303 and the second step plane 304 in a direction perpendicular to the front side 201_1.

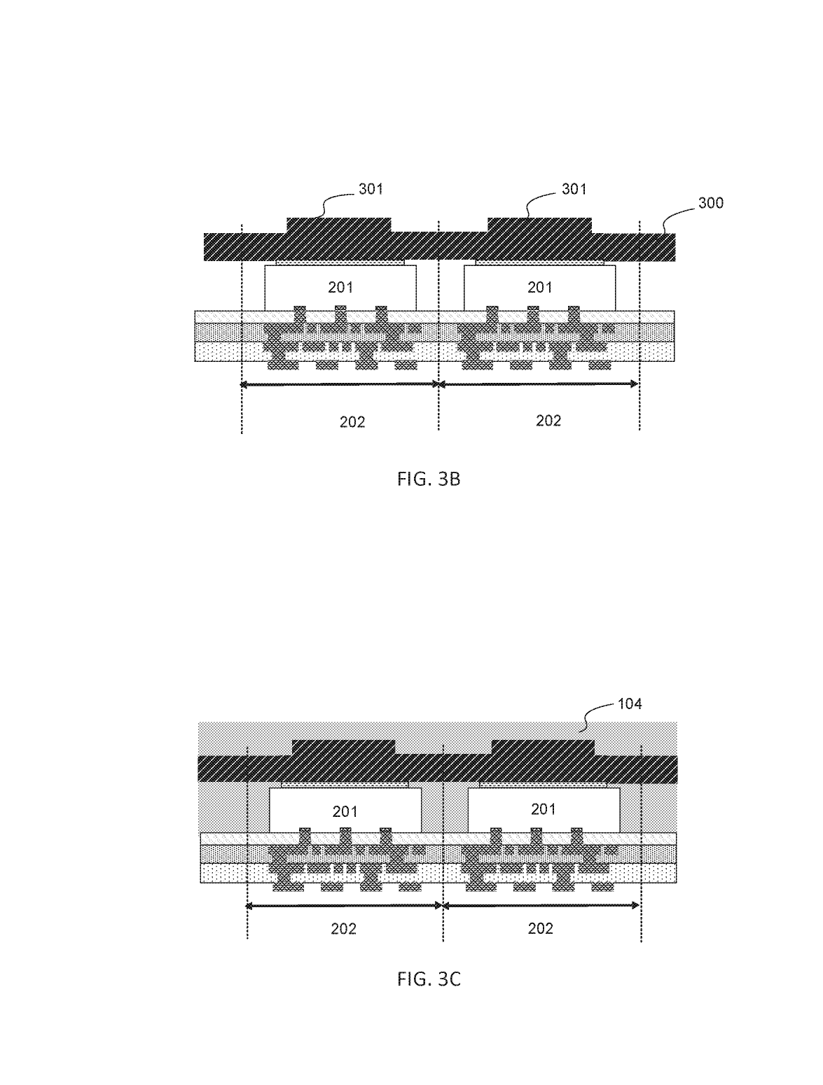

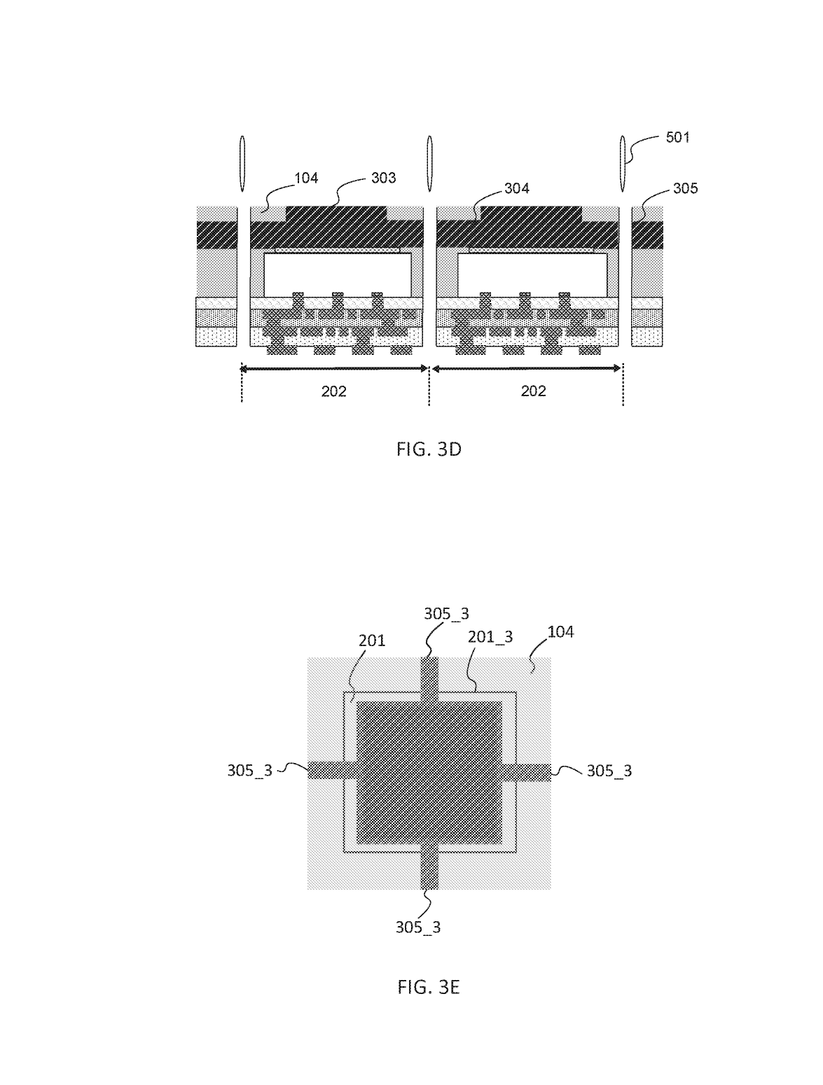

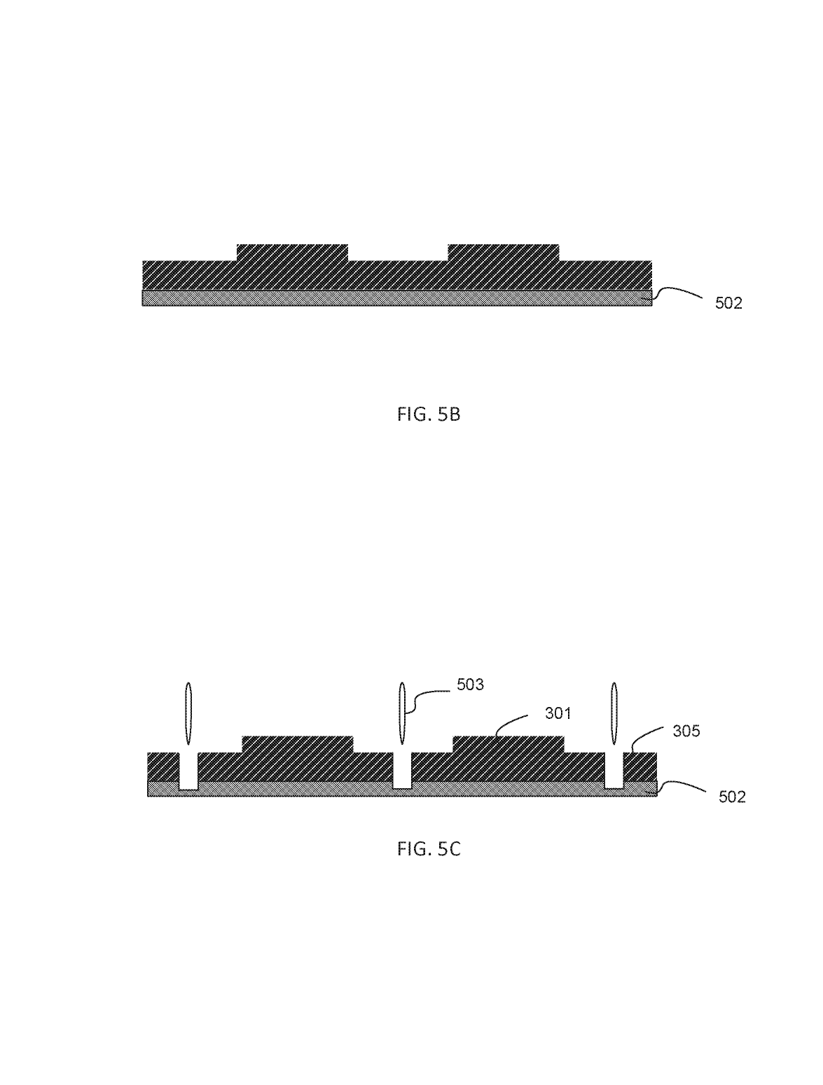

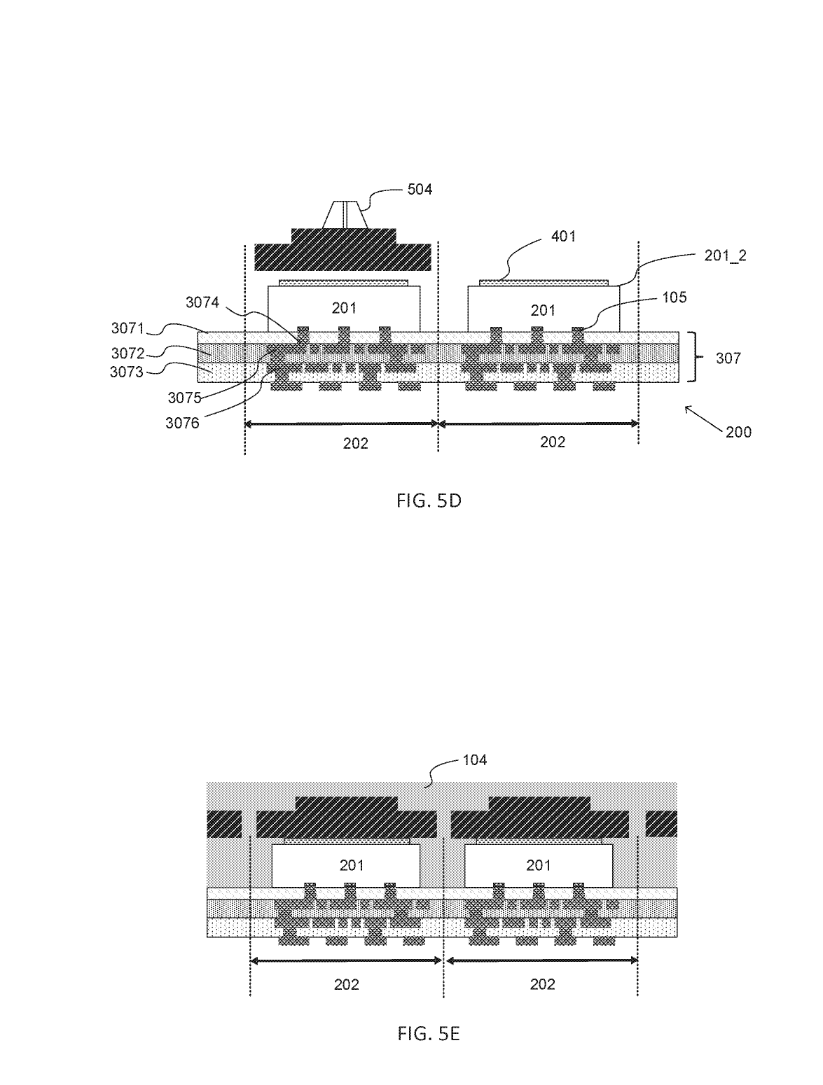

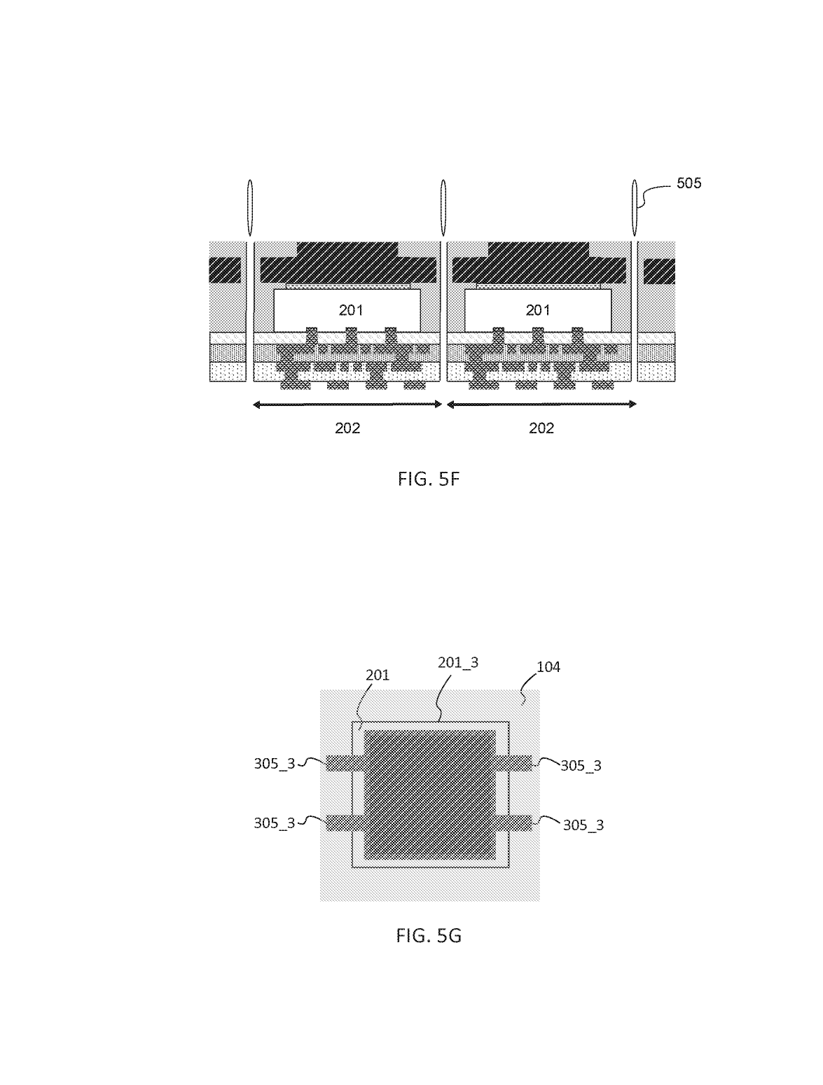

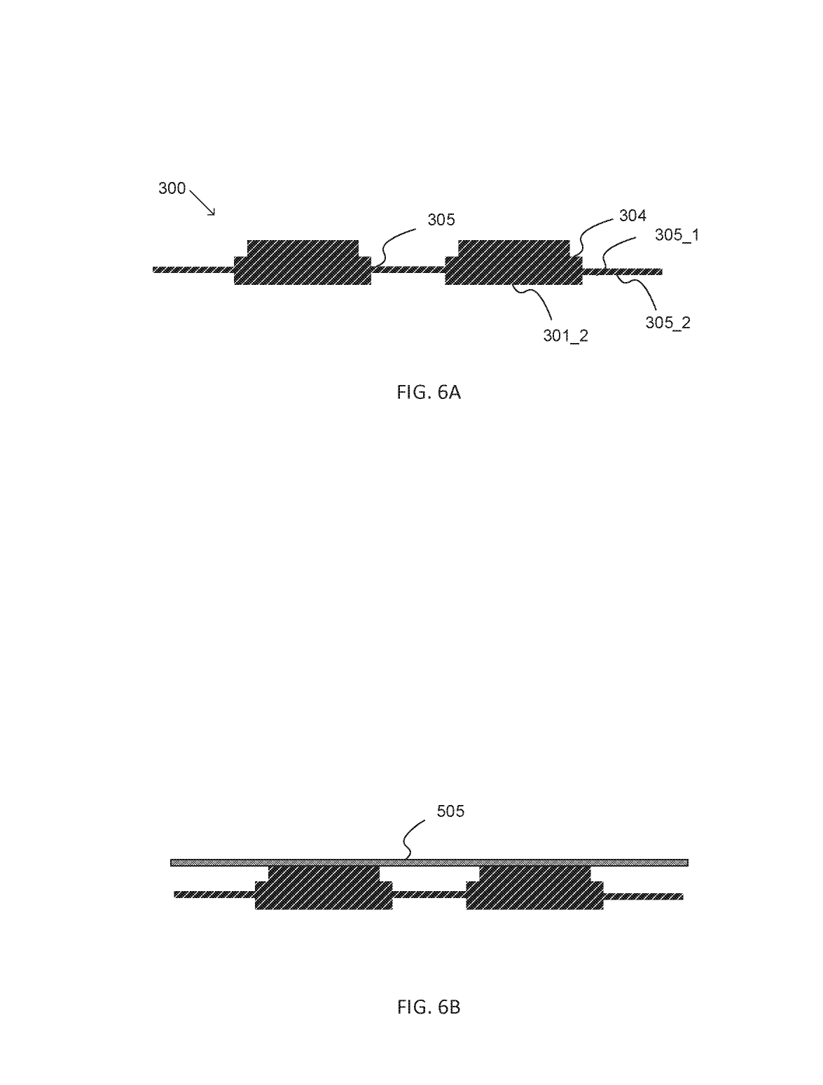

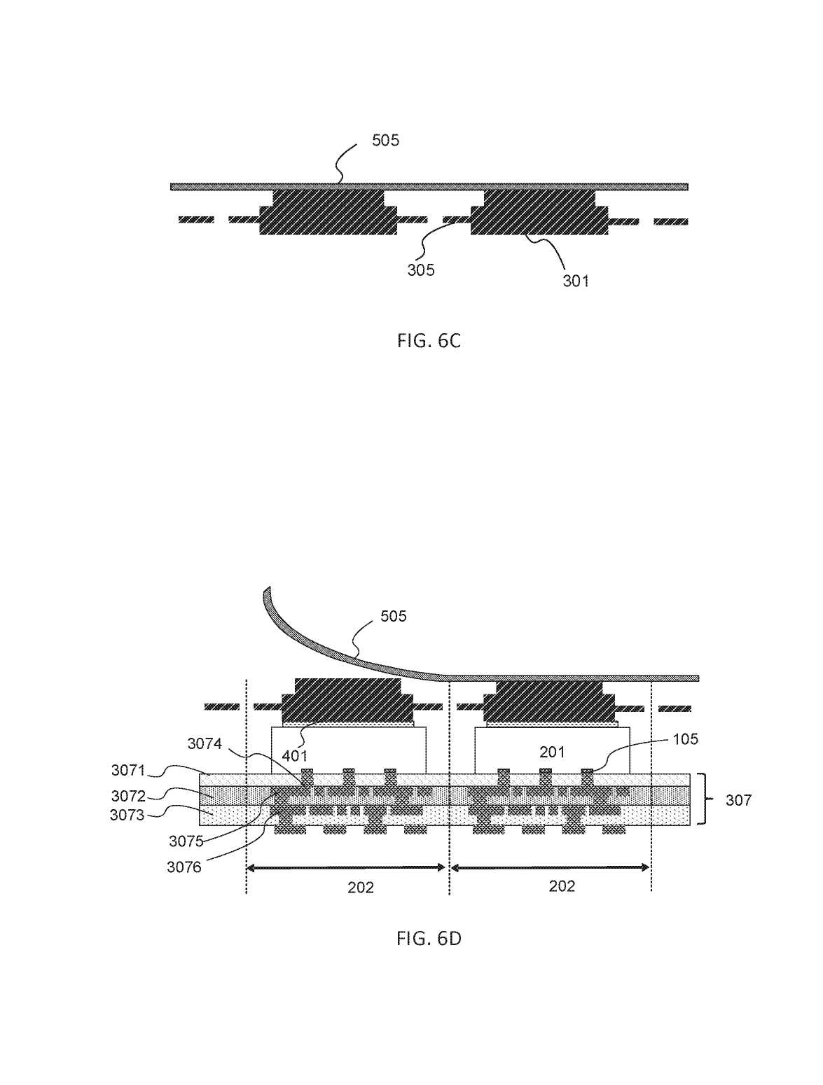

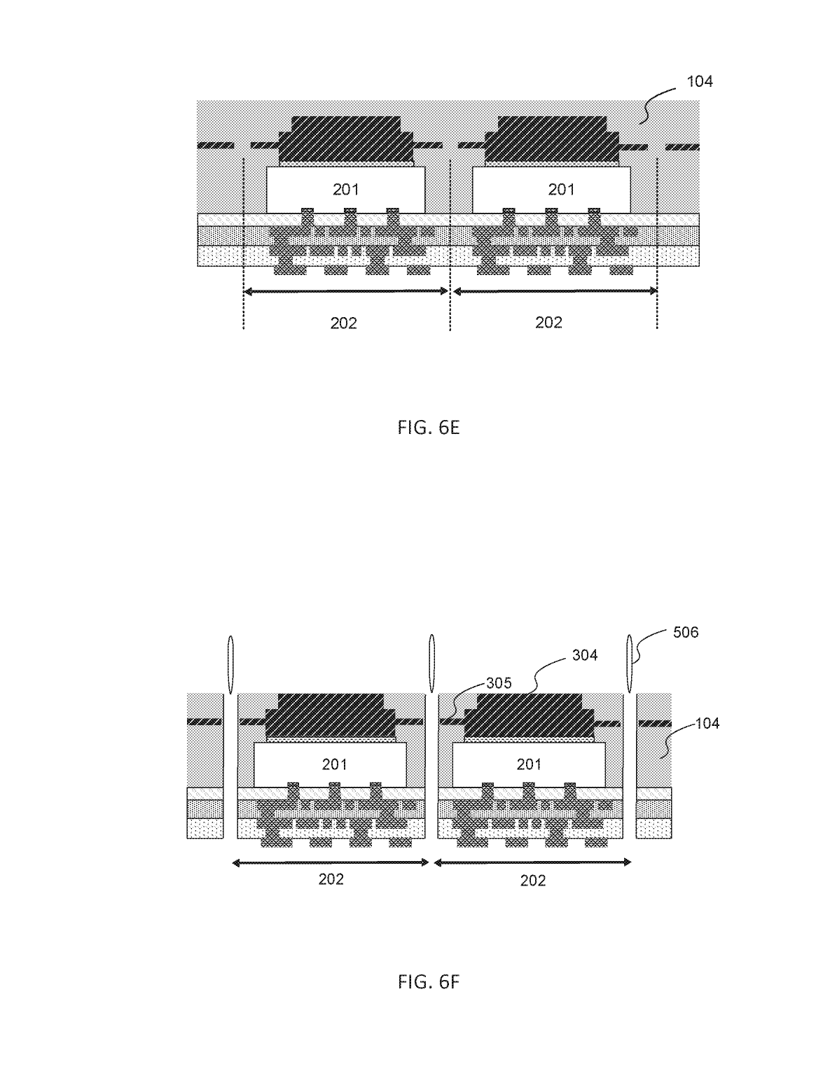

In order to manufacture the semiconductor package unit 202 disclosed in the present application, some manufacturing methods are illustrated below with reference to FIG. 3A- FIG. 3E, FIG. 5A- FIG. 5G and FIG. 6A- FIG. 6F. Those skilled in the art should understand that these drawings only show some important steps in the complete packaging method to schematically express the main concept thereof, wherein the order and specific implementation method of some steps can be changed, and these methods provided in the present application are only examples and are not intended to be limiting. Some prefabricated panel-level package components are used in these packaging methods with reference to FIG. 2A- FIG. 2D.

FIG. 2A is a schematic plan top view of a panel-level chip unit array 200 according to an embodiment of the present disclosure. FIG. 2A may be considered as a top view of the panel-level chip unit array 200 in an X-Y plane in a vertical coordinate system defined by an X axis, a Y axis, and a Z axis that are perpendicular to each other. In the example shown in FIG. 2A, the panel-level chip unit array 200 includes a plurality of chip units 201, and each of the chip units 201 may be separated from the Z-axis direction along transverse scribe lines 200X and longitudinal scribe lines 200Y after completing the entire package process to become a single semiconductor package unit 202. Those skilled in the art should understand that in the example of FIG. 2A, only one semiconductor die is contained within the chip unit 201. However, in other embodiments, the chip unit 201 may include multiple semiconductor dies.

Although the panel-level chip unit array 200 is illustrated as a rectangle in the example of the present application, this is only an example and does not limit the shape of the panel, and in other embodiments, it may be, for example, a circle, a polygon or other shapes. This application also imposes no restrictions on the panel dimensions (referring to dimensions in the X-Y plane) of the panel-level chip unit array 200. For example, for a rectangular panel, the panel dimensions may be selected from 300mm × 300mm, 580mm × 600mm, 800mm × 800mm, 240mm × 74mm, 189mm × 68mm, and other dimensions compatible with manufacturing processes. The array of chip units 201 corresponding to each semiconductor package unit 202 may be an array arrangement of any suitable number and shape (referred to herein as a top view shape on the X-Y plane), as an example, FIG. 2A illustrates a rectangular array of M rows by N columns, where both M and N are positive integers greater than or equal to 1. The panel-level chip unit array 200 on which the M * N chip units 201 arranged in an array are manufactured is packaged and then cut along the Z-axis, to obtain M * N independent semiconductor package units 202. The shape of the semiconductor package unit 202 (which refers to the shape on the X-Y plane herein) is not limited, and may be rectangular, quadrilateral, polygonal, circular, or other shapes.

FIG. 2B illustrates a planar top view of a panel-level heat sink array 300 according to an embodiment of the present disclosure. FIG. 2B may be considered as a top view of the panel-level heat sink array 300 in an X-Y plane shown in a vertical coordinate system defined by an X axis, a Y axis, and a Z axis that are perpendicular to each other. In the example shown in FIG. 2B, the panel-level heat sink array 300 includes a plurality of heat sink units 301. In one embodiment, the panel-level heat sink array 300 shown in FIG. 2B is customized for the panel-level chip unit array 200 of FIG. 2A. For ensuring excellent consistency, the shape and area of each heat sink unit 301 and the spacing between the plurality of heat sink units 301 need to be customized according to the chip units 201 of the panel-level chip unit array 200. Similar to the descriptions of FIG. 2A, although the example of FIG. 2B illustrates the panel-level heat sink unit array 300 as a rectangle, this is only an example and does not limit the shape of the panel, it may be, for example, circular, polygonal or other shapes in other embodiments. The size of the panel-level heat sink unit array 300 (which refers to a size in an X-Y plane herein) is also not limited in this application. The array of heat sink units 301 corresponding to the semiconductor package units 202 may be an array arrangement of any suitable number and shape (referred to herein as a top-view shape on the X-Y plane), as an example, FIG. 2B illustrates a rectangular array of M rows by N columns, where both M and N are positive integers greater than or equal to 1. In the package method provided below, the M * N heat sink units 301 arranged in an array are respectively provided to corresponding chip units 201, and after all package steps are completed, cutting is performed in units of semiconductor package units 202 along the Z-axis to obtain M * N semiconductor package units 202.

FIG. 2C is an enlarged view of a portion 302 of the panel-level heat sink unit array 300 of FIG. 2B. The heat sink unit 301 has a top surface 301_1 and a bottom surface 301_2. In one embodiment, the heat sink unit 301 has a stepped structure with a top surface 301_1 which is also referred to as the first step plane 303 of the heat sink unit 301. As shown in FIG. 2C, the heat sink unit 301 includes the first step plane 303 and the second step plane 304, and there is a height difference H1 between the first step plane 303 and the second step plane 304 in the Z-axis direction. The heat sink unit 301 illustratively includes a first step portion 309( shown as a gray portion in FIG. 2C) and a second step portion 310( shown as another gray portion in FIG. 2C), the first step portion 309 is vertically stacked on the second step portion 310, the first step portion 309 has the first step plane 303, the second step portion 310 has the second step plane 304, and there is the height difference H1 between the first step plane 303 and the second step plane 304 in the Z-axis direction. Those skilled in the art should understand that, in the example of FIG. 2C, the first step portion 309 and the second step portion 310 of the heat sink unit 301 have the same shape but different sizes. When viewed from a top view on the X-Y plane, the first step plane 303 and the second step plane 304 are concentrically arranged in the Z-axis direction. When the first step plane 303 and the second step plane 304 are concentrically arranged, the second step plane 304 is located around the first step plane 303, but this is only an example and is not intended to be limiting. In other embodiments, as long as a part of the second step plane 304 of the second step portion 310 is exposed relative to the first step plane 303 of the first step portion 309 to form at least two step planes with a height difference, it is ensured that the heat sink unit 301 has the stepped structure, which is consistent with the spirit of the present application and is included in the protection scope of the present application. Although the present application only shows a structure including two step portions (i.e., the first step portion 309 and the second step portion 310) , a structure including more step portions obviously conforms to the spirit of the present application and is included in the protection scope of the present application. In one embodiment, the panel-level heat sink array 300 could be fabricated by etching an entire piece of thermally conductive metal sheet (e.g., a copper plate). By etching the thermally conductive metal sheet, the first step plane 303 and the second step plane 304 of the heat sink unit 301 can be manufactured as a single integrated structure, eliminating the need for separate fabrication and subsequent assembly.

With continued reference to FIG. 2B, the plurality of heat sink units 301 in the M * N array are connected by connection ribs 305, and other regions are hollow regions 308. The connection ribs 305 link adjacent heat sink units 301 to provide support for them and connect them to the frame 306, thereby forming the panel-level heat sink array 300. Those skilled in the art should understand that, although in the examples of FIG. 2B and FIG. 2C, each heat sink unit 301 is connected to four connection ribs, and the four connection ribs (i.e., 305a, 305b, 305c and 305d in FIG. 2C) are respectively arranged in the middle of the four sides of the rectangular heat sink unit 301 and are respectively arranged perpendicular to the four sides, this is only an example and is not intended to be limiting. In the example of FIG. 2C, the first plane 305_1 of the connection ribs 305 (i.e., 305a, 305b, 305c and 305d in FIG. 2C) is coplanar with the second step plane 304, and the second plane 305_2 of the connecting ribs 305 (i.e., 305a, 305b, 305c and 305d in FIG. 2C) is coplanar with the bottom surface 301_2 of the heat sink unit 301. FIG. 2D is an enlarged view of a portion 302 of another embodiment of the panel-level heat sink unit array 300 shown in FIG. 2B. The difference between FIG. 2D and FIG. 2C is that the first plane 305_1 of the connection rib 305 is not coplanar with the second step plane 304, and the second plane 305_2 of the connection rib 305 is coplanar with the bottom surface 301_2 of the heat sink unit 301. Those skilled in the art should understand that the schematic diagrams of FIG. 2C and FIG. 2D are only examples, and in other embodiments, the second plane 305_2 of the connection rib 305 may not be coplanar with the bottom surface 301_2 of the heat sink unit 301, and/or the first plane 305_1 of the connection rib 305 may not be coplanar with the second step plane 304. In an embodiment, the panel-level heat sink array 300 could be fabricated by etching a whole piece of thermally conductive metal sheet (for example, a copper plate), and the hollow region 308, the connection rib 305 and the heat sink units 301 may be integrally manufactured by etching the thermally conductive metal sheet, without the need to be manufactured separately and then assembled. In the example of FIG. 2C, since the first plane 305_1 and the second plane 305_2 of the connecting rib 305 are respectively coplanar with the second step plane 304 and the bottom surface 301_ 2 of the heat sink unit 301, the first plane 305_ 1 of the connecting rib 305 may be formed in the same etching step as the second step plane 304, and the second plane 305_ 2 of the connecting rib 305 may be formed in the same etching step as the bottom surface 301_ 2 of the heat sink unit 301, which will help to reduce the manufacturing difficulty of the heat sink array 300 manufactured into a whole panel shape and reduce the cost.

FIG. 2E illustrates a planar top view of a panel-level heat sink array 400 according to another embodiment of the present disclosure, and FIG. 2F illustrates a planar top view of a panel-level heat sink array 500 according to another embodiment of the present disclosure. The panel-level heat sink array 400 and the panel-level heat sink array 500 are also examples customized according to the panel-level chip unit array 200 of FIG. 2A, so the shape and size of each heat sink unit 301 and the spacing between heat sink units 301 need to be customized according to the chip unit 201 and the panel-level chip unit array 200, so as to ensure that the heat sink units 301 provided in the semiconductor package units 202 have good consistency. In FIG. 2E, each heat sink unit 301 is connected to four connection ribs, and the difference from FIG. 2B lies in that four connection ribs 305( 305e, 305f, 305g, and 305h in FIG. 2E) are respectively connected to four corners of the rectangular heat sink unit 301. In FIG. 2F, each heat sink unit 301 is connected to four connection ribs, and a difference from FIG. 2B lies in that two connection ribs 305( 305i and 305j in FIG. 2F) are connected to one side of the rectangular heat sink unit 301 and are disposed perpendicular to the side, and the other two connection ribs( 305k and 305l in FIG. 2F) are connected to an opposite side of the rectangular heat sink unit 301 and are disposed perpendicular to the opposite side. Similar to what shown in FIG. 1A, at least a part of the connection rib 305 is retained in the semiconductor package unit 202, and those skilled in the art should understand that in the semiconductor package unit 202 formed by using different panel-level heat sink arrays 300 as shown in FIG. 2E, FIG. 2F or FIG. 2B, the positions of the retained connection ribs 305 are different, which helps to select an appropriate layout according to the footprints of other components (e.g., other passive components) in a specific semiconductor package unit. Similar to the description related to the example of FIG. 2B, the first plane 305_1 of the connection rib 305 may be disposed coplanar/non-coplanar with the second step plane 304, and the second plane 305_2 of the connection rib 305 may be disposed coplanar/non-coplanar with the bottom surface 301_ 2 of the heat sink unit 301.

FIG. 3A- FIG. 3E, FIG. 5A- FIG. 5G, and FIG. 6A- FIG. 6F illustrate cross-sectional views or top views of some stages in a method of manufacturing the semiconductor package unit with the heat sink unit 301. In these embodiments, although FIG. 2B, FIG. 2C, FIG. 2F or other panel-level heat sink arrays are illustrated as an example, those skilled in the art should understand that, for fabricating the semiconductor package unit 202 similar to that shown in FIG. 1A. these packaging methods may be completed by using the panel-level heat sink arrays as shown in FIG. 2D, FIG. 2E or other panel-level heat sink arrays that are not shown but conform to the concept disclosed in the present application. Although these embodiments take the panel-level chip unit array 200 shown in FIG. 2A as an example, those skilled in the art should understand that the packaging method may be completed by using any other panel-level chip unit array 200 that conforms to the concept disclosed in the present application.

Referring to FIG. 3A, the panel-level chip unit array 200( for example, the panel-level chip unit array 200 of FIG. 2A) is provided, and the panel-level chip unit array 200 includes a plurality of chip units 201 arranged in an array and a carrier board carrying the chip units 201. In the example of FIG. 3A, the carrier is illustrated as the laminated substrate 307. The laminated substrate 307 includes multiple dielectric layers (e.g., a first dielectric layer 3071, a second dielectric layer 3072, a third dielectric layer 3073, etc.) and multiple redistribution metal layers (e.g., metal pillars 3074, a first redistribution metal layer 3075, a second redistribution metal layer 3076, etc.). The laminated substrate 307 may be manufactured by manufacturing an electroplating mask (for example, a dry film such as polyimide), patterning the electroplating mask, manufacturing a redistribution metal layer by using the patterned electroplating mask as a mask for electroplating, removing the electroplating mask, and then manufacturing a dielectric layer by using a process such as lamination (rolling). Alternatively, the steps of manufacturing the dielectric layer, patterning the dielectric layer (for example, by laser drilling or the like), and manufacturing the redistribution metal layer by using the patterned dielectric layer as a mask and electroplating are repeated, which will not be further discussed in the present disclosure. The laminated substrate 307 corresponds to the plurality of chip units 201, wherein multiple metal pillars 3074 within the laminated substrate 307 are positionally aligned one-to-one with multiple metal pads 105 of each chip unit 201 of the panel-level chip unit array 200. Those skilled in the art should understand that the laminated substrate 307 could have an integral/monolithic structure. The size of the laminated substrate 307 determines the panel size of the panel-level chip unit array 200.

The similarity between the example in FIG. 3A and the example in FIG. 2A lies in that only one semiconductor die (labeled as 201) is contained within the chip unit 201. Each semiconductor die 201 may include a substrate on which integrated circuits are fabricated. Those skilled in the art should understand that the substrate may include a semiconductor material such as silicon (Si), a compound semiconductor material such as silicon germanium (SiGe), or other forms of substrates such as silicon-on-insulator (SOI). Integrated circuits fabricated in the substrate may be coupled to external circuit through multiple metal pads 105. The side of semiconductor die 201 on which metal pads 105 are fabricated may be referred to as the front side 201_1, and the side opposite to the front side 201_1 may be referred to as the back side 201_2. As shown in FIG. 3A, the adhesive material layer 401 for adhering the heat sink unit 301 is further correspondingly disposed on the back surface 201_2 of each semiconductor die 201.

Referring to FIG. 3B, in a manner of ensuring that each heat sink unit 301 is correspondingly disposed on the back side 201_2 of the corresponding chip unit 201 of each semiconductor package unit 202, the panel-level heat sink array 300(for example, as shown in FIG. 2B or FIG. 2C) is adhered to the adhesive material layer 401, so that the bottom surface 301_2 of the heat sink unit 301 is coupled to the back side 201_2 of the semiconductor die 201. In this embodiment, the sole semiconductor die (marked as 201) in each chip unit 201 is the main heat source, that is, it's the object which needs to be designed with the heat dissipation solution according to the present application, therefore, when attaching the panel-level heat sink array 300, it is necessary to ensure that each heat sink unit 301 is correspondingly disposed on the back surface 201_2 of the corresponding chip unit 201 of each semiconductor package unit 202 and keep the semiconductor package units 202 in good consistency. FIG. 3B is cross-sectional view of a portion corresponding to the panel-level heat sink array 300 along the longitudinal cutting line A-A' (i.e., along the Z-axis) in FIG. 2C. It should be understood by those skilled in the art that, in the example of FIG. 2C, the first plane 305_1 of the connection ribs 305(i.e., 305a, 305b, 305c and 305d in FIG. 2C) is coplanar with the second step plane 304, and the second plane 305_2 of the connection ribs 305( i.e., 305a, 305b, 305c and 305d in FIG. 2C) is coplanar with the bottom surface 301_2 of the heat sink unit 301, so the connection ribs 305 and the second step plane 304 cannot be distinguished from the cross-sectional view in the schematic diagram of FIG. 3B, but in fact, in the X-Y plane, the second step plane 304 is not set to have the same projection area size as the entire semiconductor package unit 202.

According to an embodiment of the present disclosure, referring to FIG. 3C, an encapsulation material layer 104（such as an epoxy molding compound layer or other plastic encapsulation material layer) may be formed after the panel-level heat sink array 300 is adhered. Referring to FIG. 3C, the encapsulation material layer 104 may wrap each of the heat sink units 103 and the connection ribs 305 and fill all the remaining hollow regions 308（not shown) of the panel-level heat sink array 300, cover and wrap the semiconductor dies 201 in each of the semiconductor package units 202, electrically isolate the semiconductor dies 201 from each other and play a role in moisture insulation and shaping the entire panel, etc. The encapsulation material layer 104 may further fill the scribe lines between the semiconductor package units 202. Referring to FIG. 3D, the encapsulation material layer 104 is then thinned, and at least a portion of the encapsulation material layer 104 is removed to expose all or at least a portion of the first step plane 303 of the heat sink unit 301. The encapsulation material layer 104 may be thinned by, for example, laser polishing, chemical polishing, mechanical polishing, or the like, or any combination thereof. Next, a singulation step is performed, and the cutting tool 501 may divide the entire panel-shaped package unit array along with the transverse cutting lanes 200X and the longitudinal cutting lanes 200Y to get a semiconductor package unit 202 similar to that shown in FIG. 1. FIG. 3E schematically shows a top view of the semiconductor package unit 202 after the singulation step, and when viewed from the top view, the end surfaces 305_3 of the multiple connection ribs 305 exceed the outer contour 201_3 of the semiconductor die 201. With this method, the multiple connection ribs 305 retained in the semiconductor package unit 202 extend from the heat sink unit 301 to the outer contour of the semiconductor package unit 202, and the end surfaces 305_3 of the multiple connection ribs 305 are exposed from the encapsulation material 104.

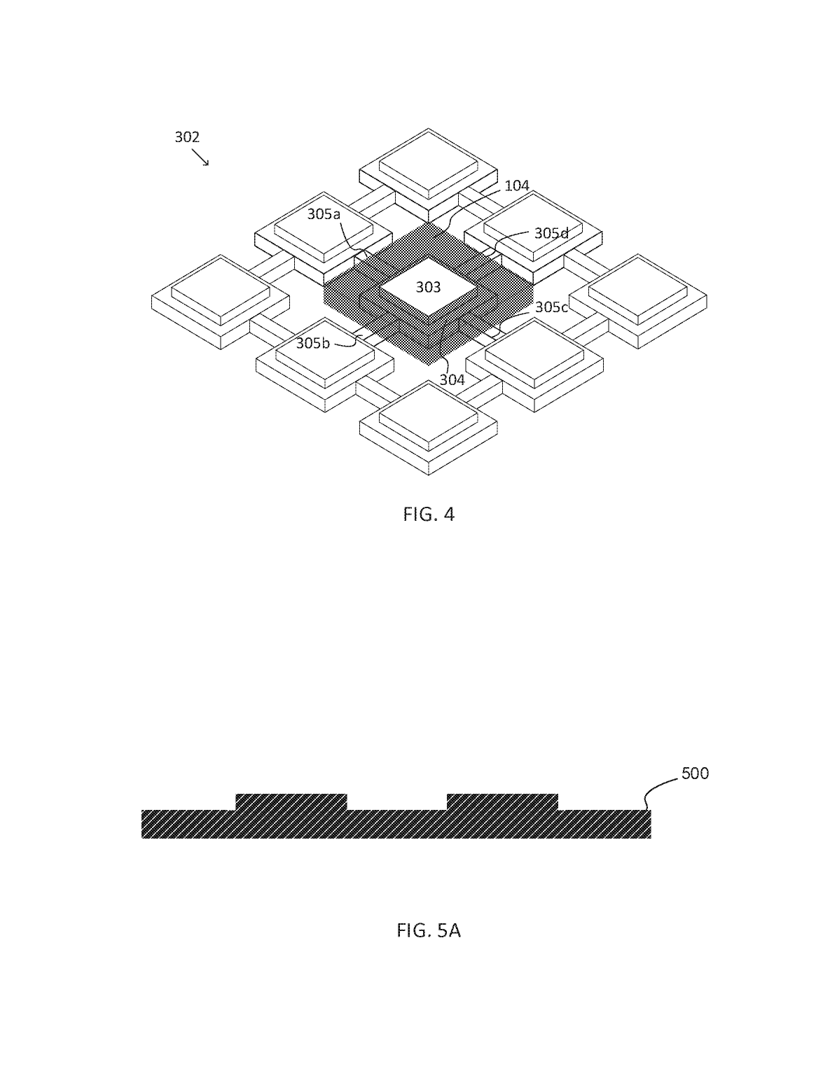

FIG. 4 shows the state of the portion 302（as illustrated in FIG. 2B and FIG. 2C) of the panel-level heat sink unit array 300, during the step shown in FIG. 3D. More specifically, FIG. 4 shows a state of the portion 302 after the encapsulation material layer 104 is thinned but before singulation. In addition, for clarity purposes, FIG. 4 only shows a state in which one single heat sink unit 301 is wrapped by the encapsulation material 104, and structures such as the semiconductor die 201 below the heat sink unit 301 are not shown in FIG. 4. Those skilled in the art should understand that in this state, other heat sink units 301 are also wrapped by the encapsulation material 104. As shown in FIG. 4, the first step plane 303 of the heat sink unit 301 is exposed to the encapsulation material 104, which can effectively conduct the heat of the heat source chip to the outside of the semiconductor package unit 202. The entire surface of the second step plane 304 of the heat sink unit 301 is covered by the encapsulation material 104, and the first plane 305_1 of the connection ribs 305 (i.e., the connection ribs 305a, 305b, 305c and 305d in FIG. 4）is also covered by the encapsulation material 104. It should be understood by those skilled in the art that although FIG. 4 shows the portion 302（as illustrated in FIG. 2B and FIG. 2C) in an intermediate state where all steps of method have not been completed. The first step plane 303 is exposed, the entire surface of the second step plane 304 is covered, and the first plane 305_1 of the connection ribs 305 is covered. This scenario is completely the same as the case of the semiconductor package unit 202 of FIG. 1 which obtained after all steps of method are completed. It can be seen that even if the packaging unit 202 is turned over, the encapsulation material 104 can still provide sufficient mechanical support for the heat sink unit 301 through contact with the entire surface of the second step plane 304 and contact with the first plane 305_1 of the connecting rib 305, ensuring that the entire heat sink unit 301 is firmly fixed in the packaging unit and is not easy to fall off.

FIG. 5A to FIG. 5G illustrate schematic cross-sectional views of some stages in a method of fabricating an integrated circuit chip (IC) package structure (such as the package unit 202 mentioned in FIG. 1A) according to an embodiment of the present disclosure. As shown in FIG. 5A, the panel-level heat sink array 500 as illustrated in FIG. 2F is provided. FIG. 5A may be regarded as a schematic diagram of a section of the panel-level heat sink array 500 cut longitudinally (i.e., along the Z direction) along the B-B′ cutting line in FIG. 2F in this step. As illustrated in FIG. 5A, since the first plane 305_1 of the connection rib 305 is coplanar with the second step plane 304, and the second plane 305_2 of the connection rib 305 is coplanar with the bottom surface 301_2 of the heat sink unit 301, so that the connection rib 305 and the second step plane 304 cannot be distinguished from the cross-sectional view in the schematic diagram of FIG. 5A, but in fact, adjacent heat sink units 301 are connected by the connection ribs 305.

Referring to FIG. 5B, the panel-level heat sink array 300 is attached to a first carrier film/board 502. The first carrier film/substrate 502 possesses sufficient thickness and strength to provide adequate support for the panel-level heat sink array 500, thereby ensuring its flatness, and meanwhile, the carrier film/plate 502 also has sufficient adhesion.

Referring to FIG. 5C, a cutting tool 503 is used to cut the panel-level heat sink array 500, which is mounted on the first carrier film/substrate 502, thereby simulating the heat sink unit 301. Those skilled in the art should understand that in this embodiment, after cutting, each heat sink unit 301 also has parts of the connection ribs 305 connected thereto. Since each heat sink unit 301 will be used to be correspondingly disposed on the back surface 201_2 of the corresponding chip unit 201 of each semiconductor package unit 202 after cutting, it is necessary to ensure the consistency of the heat sink unit 301 and its connection ribs 305 during cutting. In one embodiment, the cutting tool 503 will cut at least a portion of the first carrier film/plate 502. Due to the adhesion of the first carrier film/board 502, after the singulation is completed, each heat sink unit 301 can still be kept at its original position on the first carrier film/board 502 without falling or shifting, that is, each heat sink unit 301 still remains in an array arrangement.

Referring to FIG. 5D, the panel-level chip unit array 200 is provided, it includes multiple chip units 201 arranged in an array and a carrier board (for example, the laminated substrate 307 in FIG. 5D) carrying these chip units 201. In an embodiment, the panel-level chip unit array 200 may be provided in the same manner as that in FIG. 3A, and details are not described herein again. A vacuum suction nozzle 504 is used to pick the heat sink unit 301(on which the connection ribs 305 remain) and attach it to the adhesive material layer 401 provided on the back surface 201_2 of each semiconductor die 201. Repeat the aforementioned pick-and-attach operation until the heat sink unit 301 is installed for each semiconductor die 201 of the panel-level chip unit array 200.

Referring to FIG. 5E, after attaching the heat sink unit 301, the encapsulation material layer 104(for example, an epoxy molding compound layer or another molding material layer) may be formed. Referring to FIG. 5E, the encapsulation material layer 104 may wrap the heat sink units 103 and the connection ribs 305 and fill the space between the adjacent connection ribs 305, cover and wrap the semiconductor dies 201 in the semiconductor package units 202, electrically isolate the semiconductor dies 201 from each other and play a role of moisture insulation and shaping the entire panel, etc. The encapsulation material layer 104 may further fill the scribe lines between the semiconductor package units 202. Referring to FIG. 5F, the encapsulation material layer 104 is thinned, and at least a portion of the encapsulation material layer 104 is removed to expose all or at least a portion of the first step plane 303 of the heat sink unit 301. The encapsulation material layer 104 may be thinned by, for example, laser polishing, chemical polishing, mechanical polishing, or the like, or any combination thereof. Next, the singulation step is performed, and another cutting tool 505 may divide the panel-level package unit array according to the transverse scribe lanes 200X and the longitudinal scribe lanes 200Y to obtain the semiconductor package unit 202 similar to that shown in FIG. 1. FIG. 5G illustrates a top view of the semiconductor package unit 202 after the singulation step, and when viewed from the top view, the end surfaces 305_3 of multiple of connection ribs 305 exceed the outer contour 201_3 of the semiconductor die 201. In one embodiment, the cutting tool 505 may cut only the encapsulation material 104 without contacting the connection ribs 305, so the connection ribs 305 retained in the semiconductor package unit 202 extend from the heat sink unit 301 to the outer contour of the package unit 202, but the end surfaces 305_3 of the connection ribs 305 are covered by the encapsulation material 104 and not exposed from the encapsulation material 104. In other embodiments, the cutting tool 505 may directly cut the connection ribs 305, and the connection ribs 305 retained in the semiconductor package unit 202 extend from the heat sink unit 301 toward the outer contour of semiconductor package unit 202 and are exposed from the encapsulation material 104.

FIG. 6A to FIG. 6C illustrate schematic cross-sectional views of some stages in a method of fabricating an integrated circuit chip (IC) package structure (such as the package unit 202 mentioned in FIG. 1A) according to an embodiment of the present disclosure. In this embodiment, the panel-level heat sink array 300 shown in FIG. 2C is not used as an example. Those skilled in the art should understand that any other heat sink array that conforms to the concept disclosed in the present application and is manufactured as a whole panel to complete the packaging method.

Referring to FIG. 6A, the panel-level heat sink array 300 is provided. In this embodiment, the first plane 305_1 of the connection rib 305 is not coplanar with the second step plane 304, and the second plane 305_2 of the connection rib 305 is not coplanar with the bottom surface 301_2 of the heat sink unit 301, so the connection rib 305 and the second step plane 304 can be distinguished from the cross-sectional view in the schematic diagram of FIG. 6A. Referring to FIG. 6B, the panel-level sink array 300 is attached to a second carrier film/board 505. The second carrier film/plate 505 possesses sufficient thickness and strength to provide adequate support for the panel-level heat sink array 300, thereby ensuring its flatness, and meanwhile, the carrier film/plate 505 also has sufficient adhesion. Referring to FIG. 6C, the panel-level heat sink array 300 carried on the second carrier film/plate 505 is cut using a cutting tool to singulate the heat sink units 301. Due to the adhesion of the second carrier film/board 505, after the singulation is completed, each heat sink unit 301 can still be kept at its original position on the second carrier film/board 505 without falling or shifting, that is, each heat sink unit 301 still remains in an array arrangement.

Referring to FIG. 6D, a panel-level chip unit array 200 is provided, it includes multiple chip units 201 arranged in an array and a carrier (for example, the laminated substrate 307 in FIG. 6D) board carrying these chip units 201. In an embodiment, the panel-level chip unit array 200 may be provided in the same manner as that in FIG. 3A, and details are not described herein again. In a manner of ensuring that each heat sink unit 301 is correspondingly disposed on the back surface 201_2 of the corresponding chip unit 201 of each semiconductor package unit 202, multiple heat sink units 301 (connection ribs 305 are retained on each heat sink unit 301) that are still retained in an array arrangement on the second carrier film/carrier plate 505 after the singulation process of FIG. 6C are adhered to the adhesive material layer 401. Subsequently, the second carrier film/plate 505 is removed.

Referring to FIG. 6E, after setting the heat sink units 301, an encapsulation material layer 104(for example, an epoxy molding compound layer or another molding material layer) may be formed. Referring to FIG. 6E, the encapsulation material layer 104 may wrap the heat sink units 103 and the connection ribs 305 and fill the spaces between adjacent connection ribs 305, cover and wrap the semiconductor dies 201 in the semiconductor package units 202 and fill the scribe lines between the semiconductor package units 201. Referring to FIG. 6F, the encapsulation material layer 104 is thinned, and at least a portion of the encapsulation material layer 104 is removed to expose all or at least a portion of the first step plane 303 of the heat sink unit 301. Next, a singulation step is performed, and a cutting tool 506 may cut along the transverse scribe lines 200X and the longitudinal scribe lines 200Y to obtain the semiconductor package unit 202 similar to that shown in FIG. 1.

The present application also provides a method of manufacturing the semiconductor package unit 202 similar to that described in FIG. 1C. In the semiconductor package unit of FIG. 1C, there is no connection ribs 305 connected to the heat sink unit 301. The method includes a same step as shown in FIG. 3A, that is, providing a pre-prepared panel-level chip unit array, where panel-level chip unit array includes multiple chip units arranged in an array, and each of the chip units includes at least one semiconductor die. The method further includes the step of disposing a single heat sink unit on the back side of the at least one semiconductor die of each chip unit. There are various methods for completing this step, for example, the step as shown in FIG. 5D may be adopted, that is, using a vacuum suction nozzle to pick the individual heat sink units 301 and place them one by one. Other manners may also be used, which are not limited herein. For example, an encapsulation material layer 104 covering the chip units may be formed on the array of chip units, and then a part of the encapsulation material layer 104 is removed to form a cavity at the position where the heat sink unit 301 is expected to be disposed on the back of each chip unit. Each cavity is filled with a metallic material by sputter deposition or in other similar manners. etching or shaping the filled metal material to form the stepped structure of the heat sink. That is, the first step portion and the second step portion of the stepped structure are formed by etching the metal filled in the cavity. The method further includes the steps of forming an encapsulation material layer, wrapping the individual heat sink units and the semiconductor die and exposing the first step plane of each heat sink unit, and performing a singulation step to obtain a plurality of semiconductor packages with integrated heat sinks.

Although the present invention has been described with reference to several typical embodiments, it should be understood that the terms used are illustrative and exemplary rather than restrictive. Since the invention can be embodied in various forms without departing from the spirit or essence of the invention, it should be understood that the above embodiments are not limited to any of the foregoing details, but should be construed broadly within the spirit and scope defined by the appended claims, and therefore all changes and modifications falling within the scope of the claims or their equivalents should be covered by the appended claims.

1. A heat sink for a semiconductor package, comprising:
a top surface;
a bottom surface which is opposite to the top surface;
at least one connection rib which is integrally fabricated with the heat sink;
wherein the at least one connection rib includes a first plane which is close to the top surface and a second plane which is opposite the first plane.

2. The heat sink of claim 1, wherein the heat sink is configured to be partially embedded in an encapsulation material of a semiconductor package with the bottom surface configured to be coupled to a back side of a semiconductor die of the semiconductor package, and wherein the top surface of the heat sink is configured to be at least partially exposed from the encapsulation material, and wherein the first plane of the at least one connection rib is configured to be completely covered by the encapsulation material.

3. The heat sink of claim 2, wherein the at least one connection rib extends from the heat sink to an outer contour of the semiconductor package, and wherein an end surface of the at least connection rib is exposed from the encapsulation material.

4. The heat sink of claim 1, wherein the heat sink includes a stepped structure, and wherein the top surface of the heat sink is a first step plane of the stepped structure; the heat sink further includes a second step plane; and wherein there is a height difference between the second step plane and the first step plane in a direction perpendicular to the top surface of the heat sink.

5. The heat sink of claim 4, wherein the first plane of the at least one connection rib is coplanar with the second step plane and the second plane of the at least one connection rib is coplanar with the bottom surface of the heat sink.

6. A heat sink for a semiconductor package, comprising:
a top surface;
a bottom surface which is opposite to the top surface; and
a stepped structure;
wherein the top surface of the heat sink is a first step plane of the stepped structure; the heat sink further includes a second step plane; and in a direction perpendicular to the top surface of the heat sink, the second step plane has a height difference from the first step plane.

7. The heat sink of claim 6, wherein the heat sink is configured to be partially embedded in an encapsulation material of a semiconductor package with the bottom surface configured to be coupled to a back side of a semiconductor die of the semiconductor package, and wherein the top surface of the heat sink is configured to be at least partially exposed from the encapsulation material, and wherein the second step plane is configured to be completely covered by the encapsulation material.

8. A panel-level heat sink array, the panel- level heat sink array includes a frame, hollow regions, multiple heat sink units arranged in an array, and connection ribs between adjacent heat sink units; wherein the connection ribs connect adjacent heat sink units and connect the heat sink units to the frame to form the panel-level heat sink array.

9. The panel-level heat sink array of claim 8, wherein each of the heat sink units includes a stepped structure, the stepped structure includes a first stepped portion and a second stepped portion, the first stepped portion is vertically stacked on the second stepped portion, the first stepped portion has a first step plane, the second stepped portion has a second step plane, and there is a height difference between the first step plane and the second step plane in a direction perpendicular to the first step plane.

10. The panel-level heat sink array of claim 8, wherein the multiple heat sink units arranged in an array and the connection ribs are integrally formed by etching a same sheet, and the first step portion and the second step portion are integrally formed by etching the same sheet.

11. A method for manufacturing a semiconductor package with an integrated heat sink:
providing a panel-level chip unit array, wherein the panel-level chip unit array includes multiple chip units arranged in an array, and each chip unit includes at least one semiconductor die;
providing a panel-level heat sink array, the panel-level heat sink array includes hollow regions, multiple heat sink units arranged in an array, and connection ribs connecting adjacent heat sink units;
disposing each heat sink unit on a back surface of the at least one semiconductor die of each chip unit, wherein each heat sink unit has at least one connection rib;
forming an encapsulation material layer, so that the encapsulation material layer wraps the heat sink units and the connection ribs;
a singulation step is performed to obtain multiple semiconductor packages with integrated heat sink.

12. The method for manufacturing a semiconductor package with an integrated heat sink of claim 11, wherein in the step of disposing each heat sink unit on the back surface of the at least one semiconductor die of each chip unit, the at least one connection rib extends outwardly from the heat sink unit beyond the outer contour of the at least one semiconductor die.

13. The method for manufacturing a semiconductor package with an integrated heat sink of claim 11, comprising: to provide the panel-level heat sink array, etching a same sheet to form the multiple heat sink units arranged in an array and the multiple connection ribs connecting adjacent heat sink units.

14. The method for manufacturing a semiconductor package with an integrated heat sink of claim 11, wherein the heat sink unit includes a stepped structure having a first step plane and a second step plane; the second step plane and the first step plane have a height difference in a direction perpendicular to the front surface of the semiconductor die; and the first step plane and the second step plane are formed by etching the same sheet.

15. The method for manufacturing a semiconductor package with an integrated heat sink of claim 11, wherein the step of disposing each heat sink unit correspondingly to each chip unit comprises: adhering the panel-level heat sink array to the adhesive material layer disposed on the back surface of each corresponding chip unit in a manner of ensuring that each heat sink unit is correspondingly disposed on the back surface of each chip unit.

16. The method for manufacturing a semiconductor package with an integrated heat sink of claim 11, wherein the step of disposing each heat sink unit corresponding to each chip unit comprises: attaching the panel-level heat sink array to a first carrier film/board; cutting the panel-level heat sink array carried on the first carrier film/board by using a cutting tool to singulate the heat sink units; and attaching the singulated heat sink units to the adhesive material layer disposed on the back side of each chip unit.

17. The method for manufacturing a semiconductor package with an integrated heat sink of claim 11, wherein the step of disposing each heat sink unit corresponding to each chip unit comprises: attaching the panel-level heat sink array on a second carrier film/board; cutting the panel-level heat sink array carried on the second carrier film/board with a cutting tool to singulate the heat sink units; in a manner of ensuring that each heat sink unit is disposed corresponding to each chip unit, attaching multiple heat sink units arranged in an array and kept on the second carrier film/board to the adhesive material layer disposed on the back of each chip unit; and tearing off the second carrier film/board.
